(19) United States
(12) Patent Application Publication
(10) Pub. No.: US 2005/0161196 A1
(43) Pub. Date: Jul. 28, 2005

(54) Heat radiator for a CPU

(76) Inventor: Hsin-Mao Hsieh, Pingtung Hsien (TW)

Correspondence Address: BACON & THOMAS, PLLC, 625 SLATERS LANE, FOURTH FLOOR, ALEXANDRIA, VA, 22314, US

(21) Appl. No.: 10/761,234

(22) Filed: Jan. 22, 2004

(51) Int. Cl. H05K 7/20

(52) U.S. Cl. 165/80.3; 361/697

(57) ABSTRACT

A heat radiator for a CPU is composed of a metal piece, a columned radiating piece and a fan. The metal piece has a top surface, a bottom surface, and a conical surface formed between the top surface and the bottom surface, wherein a diameter of the top surface is smaller than a diameter of the bottom surface. The columned radiating piece is provided outside the metal piece. The radiating piece has multiple fins radially and separately extending from a center of the columned radiating piece. A conical recess is defined at a bottom of the columned radiating piece for receiving the metal piece. The fan is mounted on a top of the columned radiating piece.

### BACKGROUND OF THE INVENTION

1. Field of the Invention

The present invention relates to a heat radiator for a CPU, and more particularly to a heat radiator which has a compact structure and a high radiating efficiency.

2. Description of Related Art

Computers in operation, especially CPUs, generate lots of heat which will damage electronic components of IC (Integrate Circuit). Thus, the CPU is generally provided with a heat radiator for lowering its temperature.

Most conventional heat radiators for the CPU have a rectangular or square shape with multiple fins mounted on an upper side thereof. However, the radiator with the rectangular or square shape will occupy a large space in the computer and has a low radiating efficiency.

Therefore, the invention provides a heat radiator for a CPU to mitigate or obviate the aforementioned problems.

### SUMMARY OF THE INVENTION

The main objective of the present invention is to provide a heat radiator for a CPU which has a compact structure and a high radiating efficiency.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a heat radiator for a CPU in accordance with the present invention;

FIG. 2 is a front view of the heat radiator in FIG. 1;

FIG. 3 is a top view of the heat radiator in FIG. 1;

FIG. 4 is a schematic view of the heat radiator installed on a mainboard; and

FIG. 5 is a cross sectional view of the heat radiator in operation.

### DETAILED DESCRIPTION OF THE PREFERRED EMBODIMENT

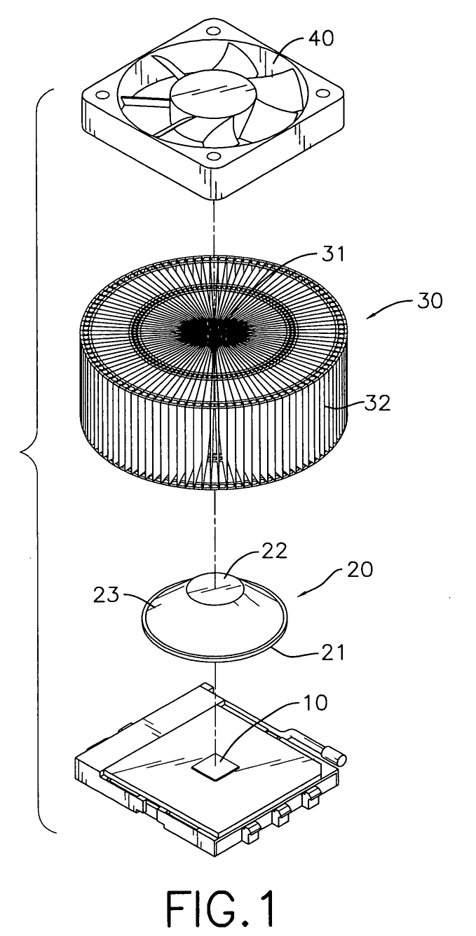

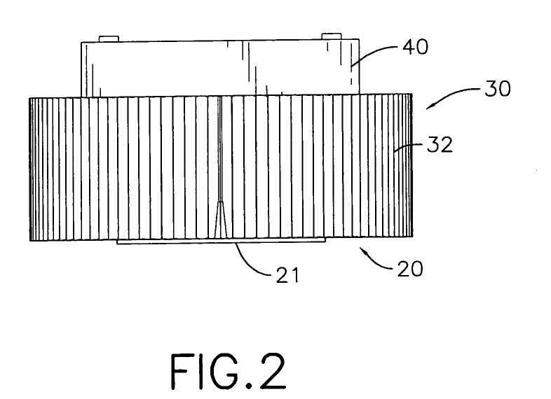

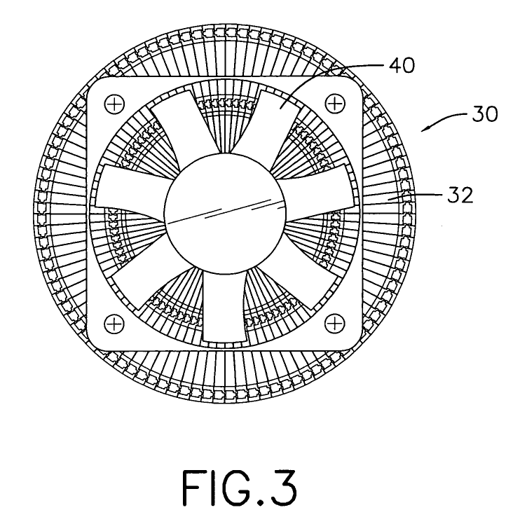

With reference to FIGS. 1-3, a heat radiator in accordance with the present invention is installed on a CPU (Central Processing Unit). The heat radiator is composed of a metal piece (20), a columned radiating piece (30) and a fan (40).

The metal piece (20) has a top surface (22), a bottom surface (21), and a conical surface (23) formed between the top surface (22) and the bottom surface (21), wherein a diameter of the top surface is smaller than a diameter of the bottom surface. The metal piece (20) can be made up of copper and has a trapezoid cross section.

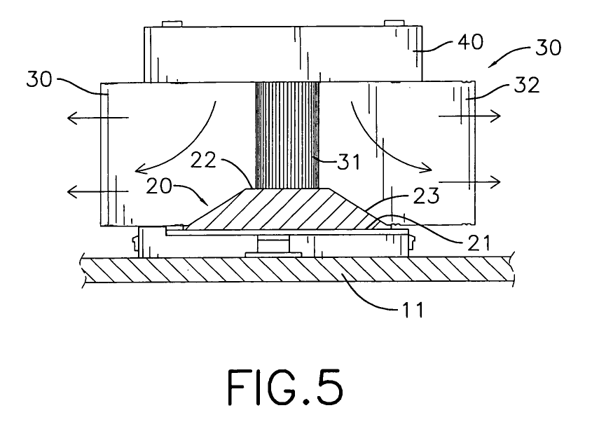

The columned radiating piece (30), being composed of multiple fins (32) radially and separately extending from a center of the columned radiating piece (30), is provided outside the metal piece (20). A conical recess (not numbered) is defined at a bottom of the radiating piece (30) to receive the metal piece (20), and inner walls defining the recess respectively abut the top surface (22) and the conical surface (23) of the metal piece (20). An opening (31) is longitudinally defined through the center of the columned radiating piece (30) and in communication with the recess, especially as shown in FIG. 5.

The fan (40) is mounted on a top of the columned radiating piece (30).

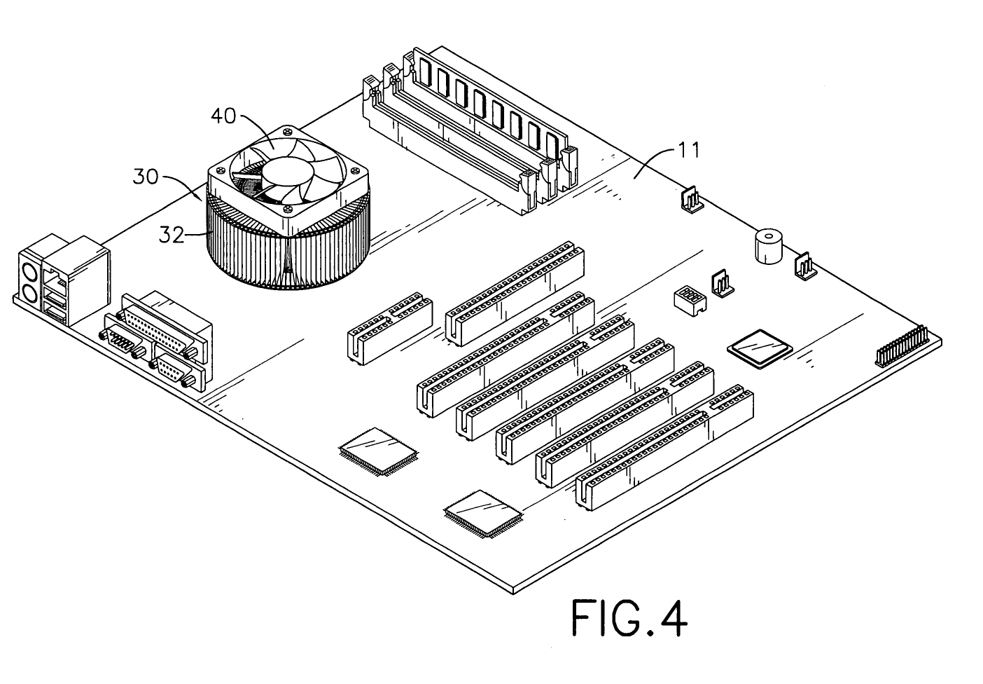

With reference to FIGS. 1, 4, 5, when a CPU (10) is installed on a mainboard (11), the CPU (10) is fully covered with the bottom surface (21) of the metal piece (20). Thus, heat generated from the CPU (10) can directly transfer into the metal piece (20). Blown by the fan (40) through the opening (31) and radiated by the fins (32), the heat can be quickly discharged to lower the temperature of the CPU (10) in a normal range, so the radiating efficiency is high. Furthermore, because the radiating piece (30) is shaped as a column, the heat radiator of the invention has a compact structure and a small size.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A heat radiator for a CPU comprising:
a metal piece having a top surface, a bottom surface, and a conical surface between the top surface and the bottom surface, wherein a diameter of the top surface is smaller than a diameter of the bottom surface;
a columned radiating piece provided outside the metal piece, the radiating piece having multiple fins radially and separately extending from a center of the columned radiating piece, and a conical recess with inner walls defined at a bottom of the columned radiating piece for receiving the metal piece; and
a fan mounted on a top of the columned radiating piece.

2. The heat radiator as claimed in claim 1, wherein the inner walls defining the recess of the radiating piece respectively abut the top surface and the conical surface of the metal piece.

3. The heat radiator as claimed in claim 1, wherein the columned radiating piece has an opening longitudinally defined through the center of radiating piece.

4. The heat radiator as claimed in claim 1, wherein a cross section of the metal piece is trapezoid.

5. The heat radiator as claimed in claim 1, wherein the metal piece is made of copper.

6. The heat radiator as claimed in claim 1, wherein the fins are made of copper.
